(19) United States
(12) Patent Application Publication
(10) Pub. No.: US 2020/0195408 A1
(43) Pub. Date: Jun. 18, 2020

(54) PUNCTURING OF ENHANCED MOBILE BROADBAND

(71) Applicant: Nokia Technologies Oy, Espoo (FI)

(72) Inventors: Jens Steiner, Klarup (DK); Klaus Pedersen, Aalborg (DK); Guillermo Pocovi, Aalborg (DK)

(21) Appl. No.: 16/609,090

(22) PCT Filed: Apr. 30, 2018
(86) PCT No.: PCT/IB2018/052987

§ 371 Date: Oct. 28, 2019

Related U.S. Application Data
(60) Provisional application No. 62/502,345, filed on May 5, 2017.

(51) Int. Cl. H04L 5/00; H04W 72/04; H04L 1/18; H04L 1/00; H03M 13/09

(52) U.S. Cl. CPC H04L 5/0055; H04W 72/042; H04W 72/0446; H03M 13/09; H04L 5/0044; H04L 1/0061; H04L 1/1819

(57) ABSTRACT

Various communication systems may benefit from puncturing of enhanced mobile broadband transmissions due to low latency communications. It may be helpful to manage the puncturing of enhanced mobile broadband transmissions. A method may include replacing by a base station at least one code block in an enhanced mobile broadband transport block transmission with a low latency communication transmission. The method may also include transmitting the enhanced mobile broadband transport block with the at least one replaced code block with the low latency communication transmission to a user equipment. In addition, the method includes transmitting the replaced at least one code block from the base station to a user equipment using other resources.

### CROSS REFERENCE TO RELATED APPLICATION

This application claims priority to U.S. Provisional Patent Application No. 62/502,345 filed on May 5, 2017. The entire content of the above-referenced application is hereby incorporated by reference.

### BACKGROUND

### Field

Various communication systems may benefit from puncturing of enhanced mobile broadband transmissions due to low latency communications. It may be helpful to manage the puncturing of enhanced mobile broadband transmissions.

### Description of the Related Art

Recent third generation partnership project (3GPP) technology, such as fifth generation (5G) New Radio (NR) technology, has been designed to support enhanced mobile broadband (eMBB) transmissions. In addition, 5G NR is able to multiplex different traffic having diverse requirements. For example, eMBB may be multiplexed with sporadically arriving low latency communication (LLC) traffic in the downlink direction. While the network may reserve bandwidth for LLC traffic, it may be beneficial to allow the LLC traffic to puncture the eMBB traffic instead of reserving resources for LLC traffic due to sporadic nature of LLC traffic.

Allowing LLC traffic to puncture the eMBB traffic means that a longer ongoing eMBB allocation is overridden by more urgent LLC transmissions. An indication of ultra-reliable LLC (URLLC) transmission is therefore dynamically signaled to an eMBB user equipment to help facilitate demodulation and decoding. In other words, the indication can then be dynamically signaled to a user equipment, whose assigned eMBB downlink resources have partially been preempted by LLC traffic.

### SUMMARY

According to certain embodiments, an apparatus may include at least one memory including computer program code, and at least one processor. The at least one memory and the computer program code may be configured, with the at least one processor, to cause the apparatus at least to replace at least one code block in an enhanced mobile broadband transport block transmission with a low latency communication transmission. The at least one memory and the computer program code may also be configured, with the at least one processor, to cause the apparatus at least to transmit the enhanced mobile broadband transport block with the at least one replaced code block with the low latency communication transmission to a user equipment. In addition, the at least one memory and the computer program code may be configured, with the at least one processor, to cause the apparatus at least to transmit the replaced at least one code block to the user equipment using other resources.

An apparatus, in certain embodiments, may include means for replacing at least one code block in an enhanced mobile broadband transport block transmission with a low latency communication transmission. The apparatus may also include means for transmitting the enhanced mobile broadband transport block with the at least one replaced code block with the low latency communication transmission to a user equipment. In addition, the apparatus may include means for transmitting the replaced at least one code block to the user equipment using other resources.

According to certain embodiments, a non-transitory computer-readable medium encoding instructions that, when executed in hardware, perform a process. The process may include replacing by a base station at least one code block in an enhanced mobile broadband transport block transmission with a low latency communication transmission. The process may also include transmitting the enhanced mobile broadband transport block with the at least one replaced code block with the low latency communication transmission to a user equipment. In addition, the process may include transmitting the replaced at least one code block from the base station to the user equipment using other resources.

According to certain other embodiments, a computer program product may encode instructions for performing a process. The process may include replacing by a base station at least one code block in an enhanced mobile broadband transport block transmission with a low latency communication transmission. The process may also include transmitting the enhanced mobile broadband transport block with the at least one replaced code block with the low latency communication transmission to a user equipment. In addition, the process may include transmitting the replaced at least one code block from the base station to the user equipment using other resources.

An apparatus, according to certain embodiments, may include circuitry for replacing by a base station at least one code block in an enhanced mobile broadband transport block transmission with a low latency communication transmission. The apparatus may also include circuitry for transmitting the enhanced mobile broadband transport block with the at least one replaced code block with the low latency communication transmission to a user equipment. In addition, the apparatus may include circuitry for transmitting the replaced at least one code block from the base station to the user equipment using other resources.

According to certain embodiments, an apparatus may include at least one memory including computer program code, and at least one processor. The at least one memory and the computer program code may be configured, with the at least one processor, to cause the apparatus at least to receive from a base station an enhanced mobile broadband transport block with at least one code block replaced by a low latency communication transmission. The at least one memory and the computer program code may also be configured, with the at least one processor, to cause the apparatus at least to receive replaced at least one code block of the enhanced mobile broadband transport block from the base station using other resources.

An apparatus, in certain embodiments, may include means for receiving from a base station an enhanced mobile broadband transport block with at least one code block replaced by a low latency communication transmission. The apparatus may also include means for receiving replaced at least one code block of the enhanced mobile broadband transport block from the base station using other resources.

According to certain embodiments, a non-transitory computer-readable medium encoding instructions that, when executed in hardware, perform a process. The process may include receiving at a user equipment from a base station an enhanced mobile broadband transport block with at least one code block replaced by a low latency communication transmission. The process may also include receiving replaced at least one code block of the enhanced mobile broadband transport block at the user equipment from the base station using other resources.

According to certain other embodiments, a computer program product may encode instructions for performing a process. The process may include receiving at a user equipment from a base station an enhanced mobile broadband transport block with at least one code block replaced by a low latency communication transmission. The process may also include receiving replaced at least one code block of the enhanced mobile broadband transport block at the user equipment from the base station using other resources.

An apparatus, according to certain embodiments, may include circuitry for receiving at a user equipment from a base station an enhanced mobile broadband transport block with at least one code block replaced by a low latency communication transmission. The apparatus may also include circuitry for receiving replaced at least one code block of the enhanced mobile broadband transport block at the user equipment from the base station using other resources.

According to certain embodiments, a method may include replacing by a base station at least one code block in an enhanced mobile broadband transport block transmission with a low latency communication transmission. The method may also include transmitting the enhanced mobile broadband transport block with the at least one replaced code block with the low latency communication transmission to a user equipment. In addition, the method includes transmitting the replaced at least one code block from the base station to the user equipment using other resources.

In a further variant, the method may include generating and transmitting a reservation signal from the base station to the user equipment. The reservation signal may include a generated transport block cyclic redundancy check for a non-punctured part of the enhanced mobile broadband transport block.

In another variant, the method may include receiving an acknowledgement or a negative acknowledgement from the user equipment relating to a non-punctured part of the enhanced mobile broadband transport block.

In a variant, the method may include at least one of regenerating or reencoding at least one code block in the enhanced mobile broadband transport block including a new transport block cyclic redundancy check relating to a non-punctured part of the enhanced mobile broadband transport block.

In yet another variant, the at least one code block may be regenerated to include an original transport block cyclic redundancy check.

In another variant, the transmitting of the at least one regenerated code block may occur at an end of a retransmission.

In an additional variant, the transmitting of the regenerated at least one code block may occur in a subsequent transmission time interval.

an additional variant, the transmitting of the regenerated at least one code block may occur after feedback may be received at the base station from the user equipment.

In a further variant, the method may include transmitting at least one other code block within the enhanced mobile broadband transport block that is not the replaced at least one code block.

According to a certain embodiment, a method may include receiving at a user equipment from a base station an enhanced mobile broadband transport block with at least one code block replaced by a low latency communication transmission. The method may also include receiving replaced at least one code block of the enhanced mobile broadband transport block at the user equipment from the base station using other resources.

In a variant, the method may include receiving a reservation signal at the user equipment from the base station. The reservation signal may include a generated transport block cyclic redundancy check for a non-punctured part of the enhanced mobile broadband transport block.

In a further variant, the method may include decoding the received replaced at least one code block.

In another variant, the method may include transmitting an acknowledgement or a negative acknowledgement from the user equipment to the base station relating to a non-punctured part of the enhanced mobile broadband transport block.

In a further variant, the method may include receiving a regenerated or reencoded at least one code block in the enhanced mobile broadband transport block including a new transport block cyclic redundancy check relating to a non-punctured part of the enhanced mobile broadband transport block.

### BRIEF DESCRIPTION OF THE DRAWINGS

For proper understanding of the invention, reference should be made to the accompanying drawings, wherein:

FIG. 1 illustrates an example of a prior art puncturing schedule.

FIG. 2 illustrates an example of a method for processing information.

FIG. 3a illustrates an example of a code block layout.

FIG. 3b illustrates an example of a code block layout.

FIG. 3c illustrates an example of a code block layout.

FIG. 4 illustrates the benefit of considering the retransmission size according to certain embodiments.

FIG. 5 illustrates an example of a puncturing scheduling according to certain embodiments.

FIG. 6 illustrates an example of a flow diagram according to certain embodiments.

FIG. 7 illustrates an example of a puncturing scheduling according to certain embodiments.

FIG. 8 illustrates an example of signal flow diagrams according to certain embodiments.

FIG. 9 illustrates an example of signal flow diagrams according to certain embodiments.

FIG. 10 illustrates an example of signal flow diagrams according to certain embodiments.

FIG. 11 illustrates an example of a flow diagram according to certain embodiments.

FIG. 12 illustrates an example of a flow diagram according to certain embodiments.

FIG. 13 illustrates an example of a system according to certain embodiments.

### DETAILED DESCRIPTION

Certain embodiments may help to improve the efficiency of a base station transmitting eMBB traffic that has been punctured by sporadic LLC traffic or URLLC traffic, by helping to ensure that the user equipment can evaluate the correctness of the non-punctured part of the transport block. In doing so, the user equipment may accurately identify the non-punctured part of the transmission, and send an acknowledgement or negative acknowledgement to the base station. The user equipment and the base station, in certain embodiments, may therefore both be capable of identifying and understanding the non-punctured part of the transport block. Based on the feedback received from the user equipment, for example in the form of an acknowledgment or a negative acknowledgement, the base station may regenerate and retransmit at least the punctured part of the original transport block to the user equipment.

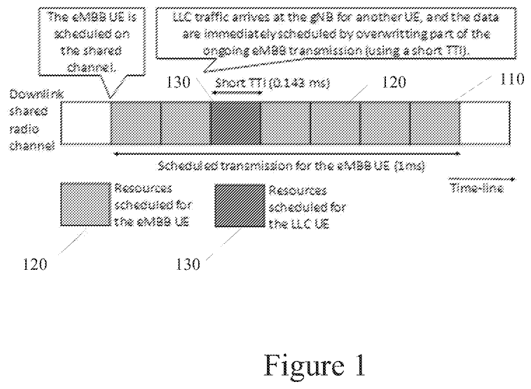

FIG. 1 illustrates an example of a puncturing schedule. In particular, FIG. 1 illustrates a transport block for downlink transmission in a shared radio channel 110, of which a long transmission time interval (TTI) including seven short TTIs 120 are scheduled for eMBB transmission. The transport block may in some embodiments be scheduled for one millisecond (ms). In other words, the TTI of the transport block may be 1 ms. As can be seen in FIG. 1, LLC traffic may arrive at the base station, such as a next generation NodeB (gNB) or a 5G NodeB, for another user equipment. The data may be immediately scheduled in resource 130 by overriding part of the ongoing eMBB transmission. The LLC traffic may be scheduled for a short TTI, which may have a duration of 0.143 ms.

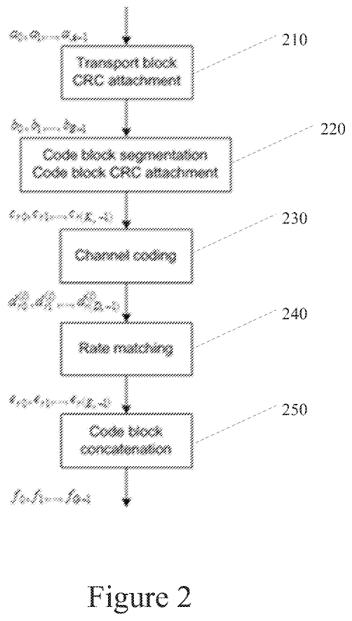

FIG. 2 illustrates an example of a method for processing information. In particular, FIG. 2 illustrates a method of encoding code blocks that is used in 3GPP Long Term Evolution (LTE) or LTE-advanced (LTE-A). In certain embodiments, the impact on the eMBB user equipment caused by puncturing may depend on how the information bits have been encoded, interleaved, and mapped to the physical (PHY) layer resources. As shown in FIG. 2, the transport block may be segmented into one or more code blocks.

In step 210, the transport block cyclic redundancy check (CRC) information may be attached to the transport block. In some embodiments the last code block in the transport block may include the CRC. In step 220, the transport block may be segmented into one or more code blocks, and the code block CRC information is attached to at least one of the code blocks in the transport block. The number of code blocks, into which the transport block is segmented, may depend on the size of the transport block and the maximum amount of information bits per code block. For example, in LTE each code block may have a maximum of 6144 bits. In 5G NR technology, each code block may have another maximum number of bits. In steps 230 and 240, channel coding and rate matching may occur, after which the code blocks may be concatenated to reform or reconstruct the transport block, as shown in step 250.

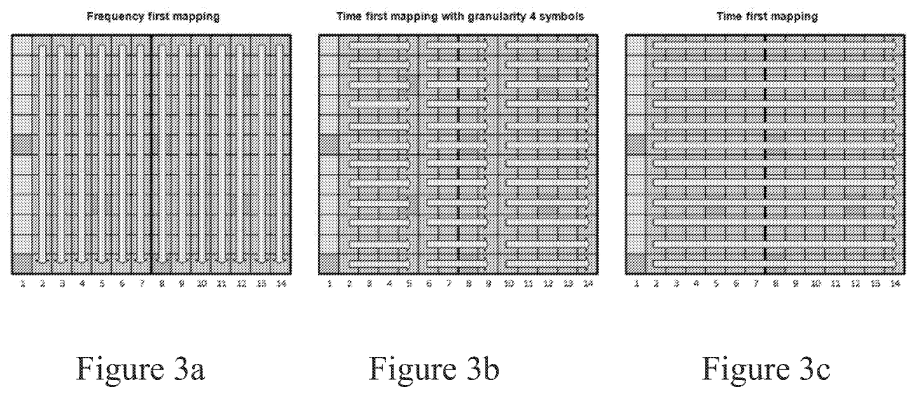

The one or more code blocks may be arranged in various ways. FIGS. 3a-3c illustrate three different examples of a code block layout. In particular, FIG. 3a illustrates frequency first mapping, in which the code blocks are arranged in sequence on a frequency domain first, as represented by the vertical arrows shown in FIG. 3a. FIGS. 3b and 3c, on the other hand, illustrate time first mapping, in which the code blocks are arranged in sequence on a time domain first, as represented by the horizontal arrows shown in FIGS. 3b and 3c.

FIG. 3b is a time first mapping with granularity. As can be seen in FIG. 3b, the time first mapping in the transport blocks has a granularity of 4 symbols. To allow for the higher reuse of PHY procedures and hardware, as well as to allow for pipeline processing having lower delays and lower processing capability demands, a frequency-first code block layout may be useful. In embodiments involving punctured transmissions, however, frequency-first code blocks may negatively affect the decoding probability of the transport blocks. FIG. 3c illustrates a time first mapping, without the granularity of FIG. 3b.

A link between the user equipment and the base station, such as a channel, may be adapted or configured for puncturing. For example, low outer loop link adaptation (OLLA) transport Block Error Rate (BLER) targets may be used for LLC traffic to fulfill its low-latency constraints. The spectral efficiency (SE) for the LLC traffic may however be degraded as an effect. In some embodiments, the OLLA BLER target may be set conservatively, for example at less than ten percent for eMBB traffic, to increase its decoding probability in case of puncturing. In certain embodiments, the LLC puncturing may be sporadic, and when the puncturing does not occur, the conservative link adaptation may degrade the spectral efficiency of the eMBB traffic. Because spectral efficiency may be of importance when serving eMBB traffic, traditional link adaptation may be preferred for eMBB, in some embodiments.

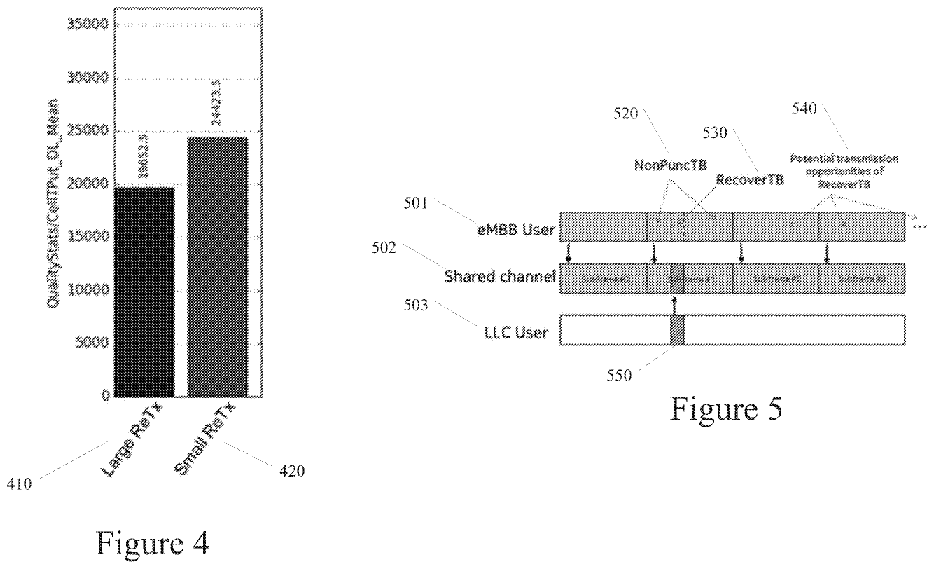

FIG. 4 illustrates the benefit of considering the retransmission size according to certain embodiments. In particular, FIG. 4 illustrates an example of anticipated average cell throughput performance in an embodiment including punctured transmissions. In particular, FIG. 4 illustrates the cell throughput of large or full-size retransmissions 410 versus the cell throughput of small retransmissions 420 after puncturing. As can be seen in FIG. 4, smaller size transmissions may have a clear benefit over full-size retransmissions.

In certain embodiments, Hybrid Automatic Repeat Request (HARQ) retransmissions may be of the same size as traditional transmissions. HARQ may be a combination of high-rate forward error-correcting coding and automatic repeat request error-control. In case of puncturing, decoding may often fail simply due to the punctured part. As shown in FIG. 4, large or full size transmissions may therefore be inefficient.

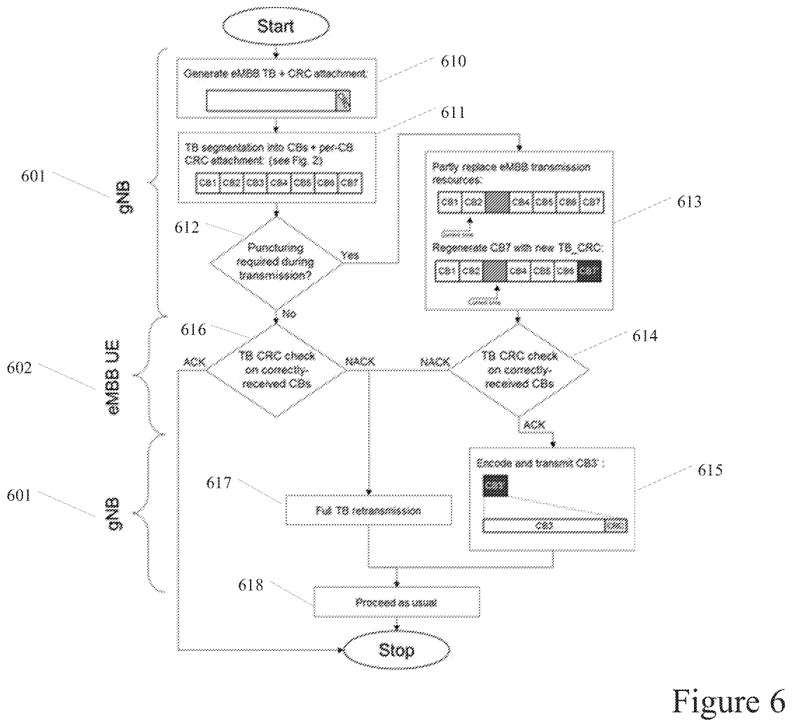

For small-size transmissions, on the other hand, the transport block error probability (BLEP) may match the OLLA BLER target. As discussed above, the OLLA BLER target may be ten percent in some embodiments. In certain embodiments, retransmission of full-size transport blocks may be triggered when a transport block is punctured. In other embodiments, as shown in FIG. 6, for example, only a regenerated eMBB part that was originally located where the eMBB transport block was punctured by the LLC traffic may be retransmitted.

FIG. 5 illustrates an example of a puncturing scheduling according to certain embodiments. As can be seen in FIG. 5, eMBB user 501 and LLC user 503 may both transmit and/or receive on a shared channel 502. FIG. 5 illustrates four transport blocks that may potentially be used by eMBB user 501. Some of the transport blocks of eMBB user 501 may be punctured, in which case we refer to the non-punctured part 520 as NonPuncTB, and the punctured part as RecoverTB 530. Other TTIs may then include potential transmission opportunities 540 for the transmission of RecoverTB. LLC user 503 may need to use scheduled resources of shared channel 502 to transmit an LLC transmission 550, and override the planned eMBB transmission on shared channel 502.

In certain embodiments, some signaling may be defined to support retransmitting only the punctured part, the punctured part being shown as RecoverTB 530 in FIG. 5. A special downlink control information (DCI) format may be defined for a transmission including the punctured part of the eMBB transport block, or referring to or identifying the punctured part. For example, the base station may inform the user equipment that part of the earlier eMBB TTI were punctured, and that the base station may not transmit the parts of the original eMBB transmission that were punctured until a later point in time. The user equipment may also disregard the corresponding soft bits from the former transmission.

In some embodiments, the transport block may be indicated by an identification, such as a HARQ identification or a new data identifier (NDI), or the indication may be implicit based on, for example, a fixed delay until the RecoverTB may be transmitted. The identification may be added on to the existing identification as part of the existing downlink control information (DCI) format. In addition, the part of the transmission to eMBB that was punctured by LCC traffic may already be known by the user equipment, in certain embodiments. When the base station is aware that the user equipment is informed of the punctured part of the transmission to eMBB, the DCI format may not need to be amended to include the identification of the punctured part.

The RecoverTB or the regenerated at least one code block that was located in an original location of the replaced or punctured at least one code block may be transmitted before an acknowledgement (ACK) or a negative acknowledgement (NACK) may be received by the base station from the user equipment. In such embodiments, the RecoverTB may be transmitted immediately following the scheduled non-punctured transport block transmission, as shown in FIG. 5. In certain embodiments, the user equipment may block or the base station may ignore the first ACK/NACK, and the base station may only rely on the ACK/NACK generated after the RecoverTB has been transmitted. The determination whether or not to block the ACK/NACK may be selected by separate signaling received by the user equipment.

In some embodiments, the RecoverTB may be transmitted only after the ACK is received by the base station. The first ACK/NACK may be a multi-bit transmission, to indicate which part of the original transport block should be retransmitted. The multi-bit transmission, however, may create extra overhead. In some other embodiments, the first ACK/NACK may be a single-bit transmission, which may not pinpoint certain parts of the transport block. A single-bit first ACK/NACK transmission may create lower overhead than the multi-bit transmission. The first ACK/NACK may refer to a non-punctured part.

The HARQ feedback, in certain embodiments, may carry useful information for the base station. The base station may then transmit a RecoverTB that includes mainly the punctured part of the transport block. The base station may also transmit additional parts of the transport block, even those parts of the transport block that were not punctured. In certain embodiments it may also be helpful for the base station and the user equipment to have the same understanding of the non-punctured part of the transport block. Certain embodiments may also allow the user equipment to evaluate whether the non-punctured part of the transport block was properly or correctly transmitted. Once the user equipment evaluates whether the non-punctured part of the transport block was properly or correctly received, and after due time of feedback to the base station, the base station may decide whether to retransmit only the punctured part of the transport block or more in the retransmission.

In certain embodiments the base station may generate a transport block CRC for a non-punctured part of the transport block, and use one or more code blocks to include the newly generated transport block CRC for non-punctured part of the transport block. The CRC for non-punctured part of the transport block may be transmitted to the user equipment in the current TTI at the end of the transport block, or at a later or earlier time. The base station may indicate to the user equipment using a reservation signal, for example conveying the newly generated transport block CRC for non-punctured part of the transport block, such that the checking of the non-punctured part of the transport block may be possible.

The base station may re-generate the transport block CRC using only non-punctured code blocks. The base station may encode and transmit the transport block CRC for non-punctured code blocks such that the non-punctured code blocks may be checked via the reservation signal. The user equipment may then perform the transport block CRC check, using the transport block CRC for non-punctured code blocks, on the set of code blocks where the code block CRC check passes. The user equipment may then send an ACK or a NACK accordingly. The base station, upon receiving an ACK from the user equipment, may send the punctured code blocks.

In certain other embodiments, the base station may re-encode a code block with the transport block CRC for non-punctured part of transport block. For example, the base station may re-generate the transport block CRC using only non-punctured code blocks, referred to as NonPuncTB_CRC, and re-encode the last code block with the original transport block CRC replaced by NonPuncTB_CRC, during the long TTI of the punctured transport block. The user equipment may then perform the transport block CRC check, using NonPuncTB_CRC, on the set of code blocks whose code block CRC check passes.

The user equipment may then send an ACK or a NACK to the base station accordingly. Upon receiving an ACK regarding the non-punctured part, the base station may send the punctured code blocks with the last code block enlarged and re-encoded with the original transport block CRC attached. The enlargement needs to be sufficient to support the original transport block CRC attachment. In certain embodiments, when the last code block in the transport block is a code block being punctured, a reservation signal may be used.

FIG. 6 illustrates an example of a flow diagram according to certain embodiments. In particular, a base station, such as gNB 601, may generate an eMBB transport block, along with a transport block CRC attachment, as shown in step 610. In step 611, the transport block may be segmented by gNB 601 into one or more code blocks, each with a per code block CRC attached. In step 612, a determination is made whether the puncturing by an LLC transmission, which may be needed by a separate user equipment other than eMBB user equipment 602, may occur. If so, gNB 601 may replace the eMBB transmission resources located in code block 3 with an LLC transmission. The last code block, which may be code block 7 in the example shown in FIG. 6, may then be regenerated with a new transport block CRC for the non-punctured part of transport block, as shown in step 613.

gNB 601 may then transport one or more code blocks to user equipment 602. In step 614, user equipment 602 may perform a transport block CRC check to determine whether the non-punctured part of the transport block was received correctly, based on correctly received code blocks. When user equipment 602 acknowledges that the non-punctured part of the transport block was correctly received, the punctured part of the transport block, which is the original code block 3 shown in FIG. 6, can be re-encoded with the original transport block CRC attached, and transmitted from gNB 601 to user equipment 602, as shown in step 615. When no puncturing is required during transmission, the user equipment may perform a transport block CRC check on whether the transport block is correctly received, as shown in step 616. If the user equipment acknowledges that the full transport block was correctly received, the transmission by gNB 601 may be stopped.

On the other hand, when the user equipment determines that the transport block CRC check fails in either step 614 or step 616, a negative acknowledgement may be sent from user equipment 602 to gNB 601. gNB 601 may then retransmit the full transport block, as shown in step 617. Once the transport block is fully retransmitted, gNB 601 may then proceed as usual, until transmission may no longer be required. Although FIG. 6 illustrates an example in which only one code block is punctured, in certain embodiments one or more LLC transmissions may occur in a single transport block, and one or more code blocks may be punctured in a single transport block. Using the process described in FIG. 6, the user equipment may evaluate whether the non-punctured part of the transport block was accurately received.

In certain embodiments, the eMBB transport block may be much larger than the LLC transport block. In embodiments in which it may be difficult to perform the eMBB transport block CRC recalculation in due time, the intermediate transport block CRC states can be cached. In such embodiments, the whole eMBB transport block may not need to be processed again.

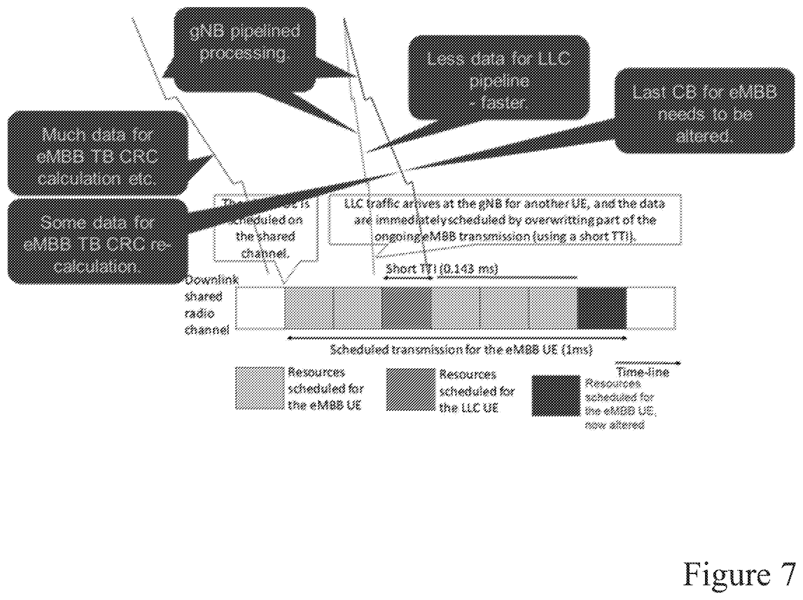

FIG. 7 illustrates an example of a puncturing scheduling according to certain embodiments. In particular, FIG. 7 illustrates the feasibility of doing eMBB transport block CRC recalculation in due time, as it may put no added or tighter time constraints on the base station than the LLC traffic.

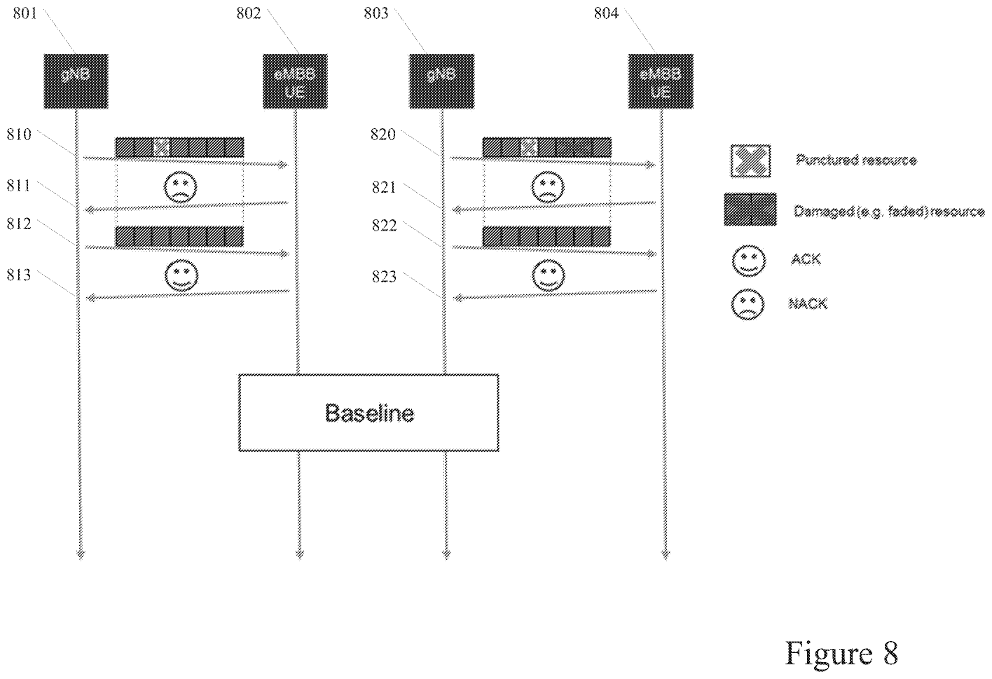

FIG. 8 illustrates examples of signal flow diagrams according to certain embodiments. In particular, FIG. 8 illustrates two scenarios in which decoding errors occur. A base station 801, such as an gNB, sends an eMBB transmission to eMBB user equipment 802 in step 810. As can be seen in the transport block in step 810, the eMBB transmission is punctured. In step 811, user equipment 802 may send a negative acknowledgement to gNB 801. In step 812, gNB 801 may transmit to eMBB user equipment 802 a new transport block, in response to which eMBB user equipment 802 sends an acknowledgment, as shown in step 813.

FIG. 8 also illustrates an eMBB transmission from gNB 803 to eMBB user equipment 804. In step 820, in addition to puncturing, a decoding error may occur due to fading or interference, for example. eMBB user equipment 804 may then send a negative acknowledgement to gNB 803, as shown in step 821, in response to which gNB 803 may retransmit the entire transport block, as shown in step 822. In step 823, eMBB user equipment 804 may send an acknowledgment indicating that the retransmitted transport block was properly received.

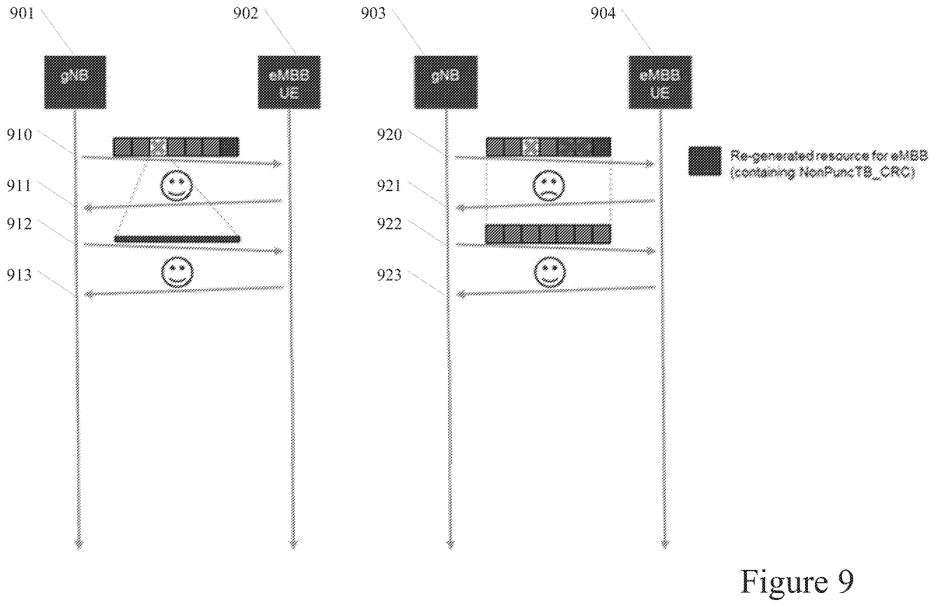

FIG. 9 illustrates an example of signal flow diagrams according to certain embodiments. In particular, FIG. 9 illustrates two scenarios in which decoding errors occur. A base station 901, such as an gNB, may send an eMBB transmission to eMBB user equipment 902 in step 910. As can be seen in the transport block in step 910, the eMBB transmission is punctured. In step 911, user equipment 902 may be aware that the eMBB transmission was punctured, and may send an acknowledgement to gNB 901. The acknowledgement may indicate to gNB 901 that the non-punctured parts of the transport block were correctly received. In step 912, gNB 901 may transmit to eMBB user equipment 902 just those one or more code blocks that were punctured by the LLC traffic. The regenerated one or more code blocks may be sent with the last code block altered to include the original transport block CRC.

FIG. 9 also illustrates an eMBB transmission from gNB 903 to eMBB user equipment 904. In step 920, in addition to puncturing, a decoding error may occur due to fading and/or interference.

eMBB user equipment 904 may then send a negative acknowledgement to gNB 903, as shown in step 921, in response to which gNB 903 may retransmit the entire transport block, as shown in step 922. In step 923, eMBB user equipment 904 may send an acknowledgment indicating that the retransmitted transport block was properly received.

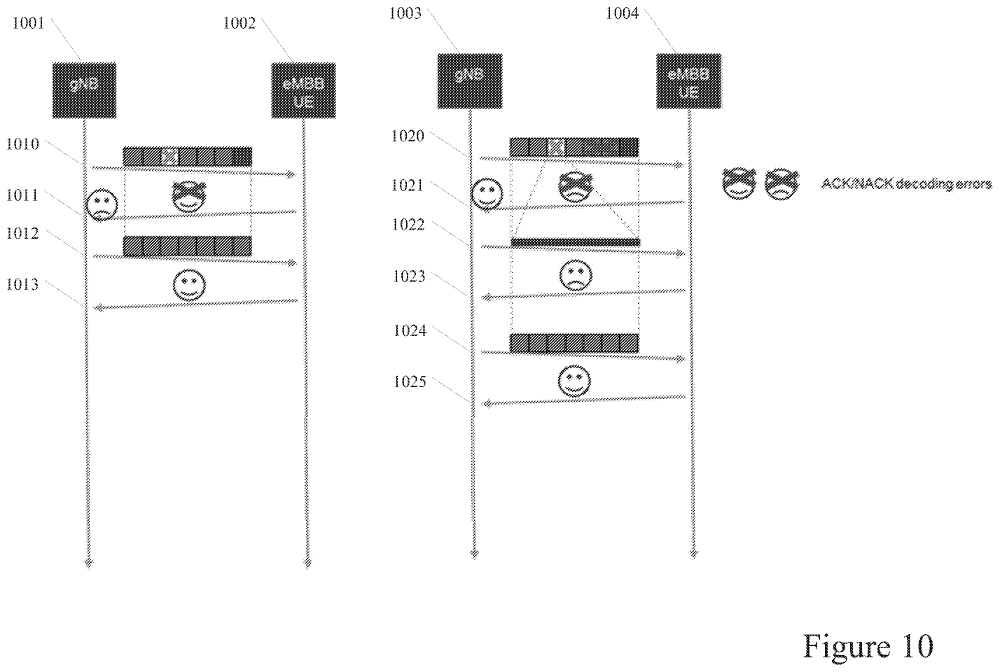

FIG. 10 illustrates an example of a signal flow diagram according to certain embodiments. In particular, FIG. 10 illustrates an eMBB transmission from gNB 1001 to user equipment 1002, and another eMBB transmission from gNB 1003 to user equipment 1004, in which a first acknowledgment or a first negative acknowledgment may be received incorrectly. In step 1010, gNB 1001 may transmit a punctured transport block to eMBB user equipment 1002. User equipment 1002 may then respond with an acknowledgment incorrectly perceived at gNB 1001 as a negative acknowledgment, as shown in step 1011. In step 1012, gNB 1001 may respond to the perceived negative acknowledgment by resending the full transport block to eMBB user equipment 1002. eMBB user equipment 1002 may then respond to gNB 1001 with an acknowledgment.

FIG. 10 also illustrates an eMBB transmission from gNB 1003 to user equipment 1004. In step 1020, the gNB 1003 may transmit a transport block with one or more code blocks punctured, along with one or more code blocks having decoding errors, to eMBB user equipment 1004. For example, one or more code blocks may be experiencing fading and/or interference that may lead to the decoding error. User equipment 1004 may then respond with a negative acknowledgment, incorrectly perceived at gNB 1003 as a positive acknowledgment, as shown in step 1021. In step 1022, gNB 1003 may respond to the perceived acknowledgment by only resending one or more code blocks that have originally been punctured by LLC transmissions to eMBB user equipment 1004.

eMBB user equipment 1004 may then respond to gNB 1003 with a negative acknowledgment, as shown in step 1023. The gNB 1003 may then retransmit the full transport block, as shown in step 1024. In step 1025, user equipment 1004 may transmit an acknowledgement to gNB 1003. The above embodiments shown in FIG. 10 may allow for the graceful handling of an incorrectly received first acknowledgment or a first negative acknowledgment. In certain cases it may also help to prevent a base station from having to wait for a higher layer windowed negative acknowledgement.

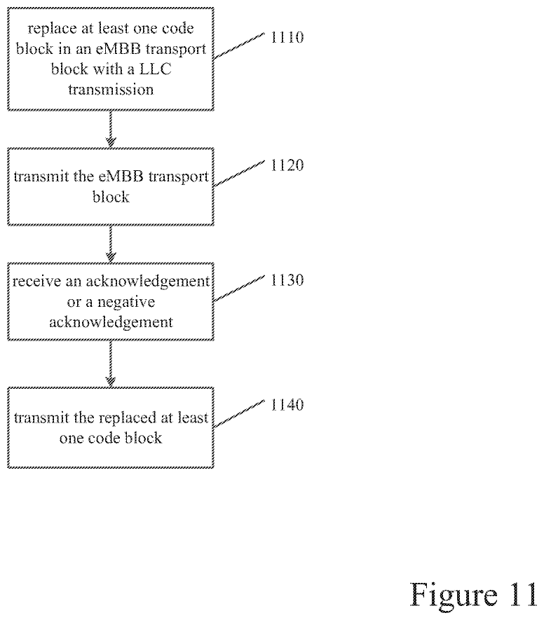

FIG. 11 illustrates an example of a flow diagram according to certain embodiments. In particular, FIG. 11 illustrates a method performed by a base station, such as a gNB. In step 1110, the base station may puncture, and therefore not transmit as originally intended, at least one code block in an eMBB transmission due to LLC transmission. In step 1120, the base station may finalize ongoing transmission, which may have been possibly modified. In other words, the base station may transmit the eMBB transport block.

In certain embodiments, as shown in step 1130, the base station may receive an acknowledgement or a negative acknowledgement from the user equipment relating to the non-punctured code blocks. In step 1140, the base station may transmit the replaced at least one code block from the base station to a user equipment. In some embodiments, a reservation signal is transmitted from the base station to the user equipment. In some possible embodiments, the base station may regenerate and/or reencode at least one code block.

In certain embodiments, the method may also include the base station generating and transmitting a reservation signal to the user equipment. The reservation signal may include a generated transport block cyclic redundancy check for a non-punctured part of the enhanced mobile broadband transport block. In some other embodiments, the method may include the base station regenerating and/or reencoding at least one code block in the enhanced mobile broadband transport block including a new transport block cyclic redundancy check relating to a non-punctured part of the enhanced mobile broadband transport block.

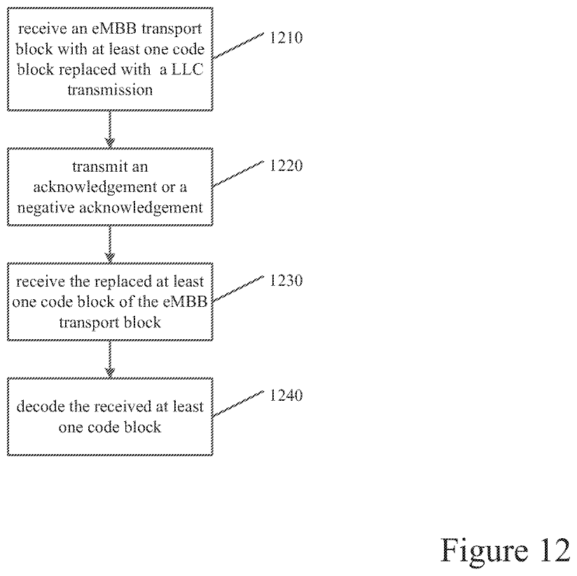

FIG. 12 illustrates an example of a flow diagram according to certain embodiments. In particular, FIG. 12 illustrates a user equipment, such as an eMBB user equipment. In step 1210, the user equipment may receive from a base station an eMBB transport block with at least one code block punctured due to low latency communication, for example. In step 1220, the user equipment may transmit an acknowledgement or a negative acknowledgement to the base station relating to non-punctured part of the transport block. In step 1230, the user equipment may receive the at least one code block from the base station that were earlier punctured, possibly in an altered form. In step 1240, the user equipment may decode the received at least one code block.

In certain embodiments, the user equipment may receive a reservation signal from the base station. In other embodiments, the user equipment may receive at least one regenerated code block.

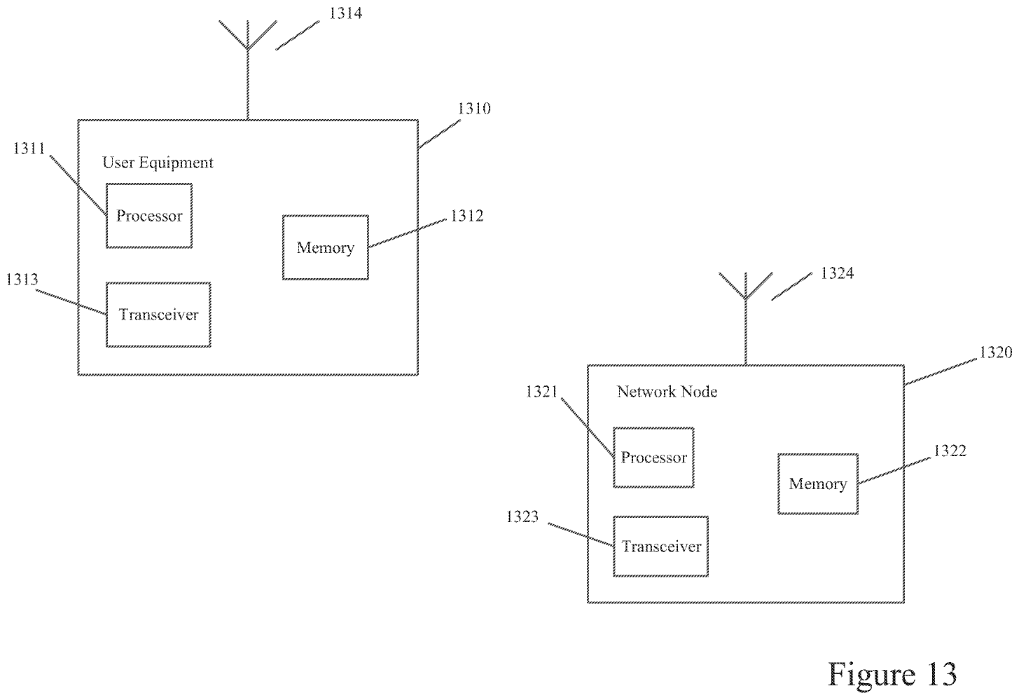

FIG. 13 illustrates an example of a system according to certain embodiments. It should be understood that each table, signal, or block in FIGS. 1-12 may be implemented by various means or their combinations, such as hardware, software, firmware, one or more processors and/or circuitry. In one embodiment, a system may include several devices, such as, for example, network node 1320 or user equipment (UE) 1310. The system may include more than one UE 1310 and more than one network node 1320. Network node 1320 may be a base station, an access point, an access node, a evolved NodeB (eNB), a New Radio Node B, a gNB, a server, a host, or any other network entity that may communicate with the UE.

Each of these devices may include at least one processor or control unit or module, respectively indicated as 1311 and 1321. At least one memory may be provided in each device, and indicated as 1312 and 1322, respectively. The memory may include computer program instructions or computer code contained therein. One or more transceiver 1313 and 1323 may be provided, and each device may also include an antenna, respectively illustrated as 1314 and 1324. Although only one antenna each is shown, many antennas and multiple antenna elements may be provided to each of the devices. Other configurations of these devices, for example, may be provided. For example, network node 1320 and UE 1310 may be additionally configured for wired communication, in addition to wireless communication, and in such a case antennas 1314 and 1324 may illustrate any form of communication hardware, without being limited to merely an antenna.

Transceivers 1313 and 1323 may each, independently, be a transmitter, a receiver, or both a transmitter and a receiver, or a unit or device that may be configured both for transmission and reception. The transmitter and/or receiver (as far as radio parts are concerned) may also be implemented as a remote radio head which is not located in the device itself, but in a mast, for example. The operations and functionalities may be performed in different entities, such as nodes, hosts or servers, in a flexible manner. In other words, division of labor may vary case by case. One possible use is to make a network node deliver local content. One or more functionalities may also be implemented as virtual application(s) in software that can run on a server.

A user device or UE 1310 may be a mobile station (MS), such as a mobile phone or smart phone or multimedia device, an IoT cellular device, a computer, such as a tablet, provided with wireless communication capabilities, personal data or digital assistant (PDA) provided with wireless communication capabilities, portable media player, digital camera, pocket video camera, navigation unit provided with wireless communication capabilities or any combinations thereof. In other embodiments, the user equipment may be replaced with a machine communication device that does not require any human interaction, such as a sensor, meter, or robot.

In some embodiments, an apparatus, such as a user equipment or a network node, may include means for carrying out embodiments described above in relation to FIGS. 1-12. In certain embodiments, at least one memory including computer program code can be configured to, with the at least one processor, cause the apparatus at least to perform any of the processes described herein.

Processors 1311 and 1321 may be embodied by any computational or data processing device, such as a central processing unit (CPU), digital signal processor (DSP), application specific integrated circuit (ASIC), programmable logic devices (PLDs), field programmable gate arrays (FPGAs), digitally enhanced circuits, or comparable device or a combination thereof. The processors may be implemented as a single controller, or a plurality of controllers or processors.

For firmware or software, the implementation may include modules or unit of at least one chip set (for example, procedures, functions, and so on). Memories 1312 and 1322 may independently be any suitable storage device, such as a non-transitory computer-readable medium. A hard disk drive (HDD), random access memory (RAM), flash memory, or other suitable memory may be used. The memories may be combined on a single integrated circuit as the processor, or may be separate therefrom. Furthermore, the computer program instructions may be stored in the memory and which may be processed by the processors can be any suitable form of computer program code, for example, a compiled or interpreted computer program written in any suitable programming language. The memory or data storage entity is typically internal but may also be external or a combination thereof, such as in the case when additional memory capacity is obtained from a service provider. The memory may be fixed or removable.

The memory and the computer program instructions may be configured, with the processor for the particular device, to cause a hardware apparatus such as network node 1320 or UE 1310, to perform any of the processes described above (see, for example, FIGS. 1-12). Therefore, in certain embodiments, a non-transitory computer-readable medium may be encoded with computer instructions or one or more computer program (such as added or updated software routine, applet or macro) that, when executed in hardware, may perform a process such as one of the processes described herein. Computer programs may be coded by a programming language, which may be a high-level programming language, such as objective-C, C, C++, C#, Java, etc., or a low-level programming language, such as a machine language, or assembler. Alternatively, certain embodiments may be performed entirely in hardware.

In certain embodiments, an apparatus may include circuitry configured to perform any of the processes or functions illustrated in FIGS. 1-12. Circuitry, in one example, may be hardware-only circuit implementations, such as analog and/or digital circuitry. Circuitry, in another example, may be a combination of hardware circuits and software, such as a combination of analog and/or digital hardware circuit(s) with software or firmware, and/or any portions of hardware processor(s) with software (including digital signal processor(s)), software, and at least one memory that work together to cause an apparatus to perform various processes or functions. In yet another example, circuitry may be hardware circuit(s) and or processor(s), such as a microprocessor(s) or a portion of a microprocessor(s), that include software, such as firmware for operation. Software in circuitry may not be present when it is not needed for the operation of the hardware.

Specific examples of circuitry may be content coding circuitry, content decoding circuitry, processing circuitry, image generation circuitry, data analysis circuitry, or discrete circuitry. The term circuitry may also be, for example, a baseband integrated circuit or processor integrated circuit for a mobile device, a network entity, or a similar integrated circuit in server, a cellular network device, or other computing or network device.

Furthermore, although FIG. 13 illustrates a system including a network node 1320 and UE 1310, certain embodiments may be applicable to other configurations, and configurations involving additional elements, as illustrated and discussed herein. For example, multiple user equipment devices and multiple base stations may be present, or other nodes providing similar functionality, such as nodes that combine the functionality of a user equipment and a base station, such as a relay node. The UE 1310 may likewise be provided with a variety of configurations for communication other than communicating with network node 1320. For example, the UE 1310 may be configured for device-to-device, machine-to-machine, or vehicle-to-vehicle communication.

The above embodiments are directed to improvements to computer-related technology, and may provide for significant improvements to the functioning of a network and/or to the functioning of the network entities within the network, or the user equipment communicating with the network. For example, the above embodiments may allow the user equipment to accurately determine whether the non-punctured part of the transport block was received correctly. This can allow the network node and the user equipment to have a similar understanding of what the non-punctured part of the transport block. In addition, certain embodiments may also lower impact on LLC delays, PHY protocol, spectral efficiency, and/or eMBB delays. This helps to reduce resource usage of the network, thereby allowing each entity within the network, and interacting with the network, to utilize those resources for other processes.

The features, structures, or characteristics of certain embodiments described throughout this specification may be combined in any suitable manner in one or more embodiments. For example, the usage of the phrases “certain embodiments,” “some embodiments,” “other embodiments,” or other similar language, throughout this specification refers to the fact that a particular feature, structure, or characteristic described in connection with the embodiment may be included in at least one embodiment of the present invention. Thus, appearance of the phrases “in certain embodiments,” “in some embodiments,” “in other embodiments,” or other similar language, throughout this specification does not necessarily refer to the same group of embodiments, and the described features, structures, or characteristics may be combined in any suitable manner in one or more embodiments.

One having ordinary skill in the art will readily understand that the invention as discussed above may be practiced with steps in a different order, and/or with hardware elements in configurations which are different than those which are disclosed. Therefore, although the invention has been described based upon these preferred embodiments, it would be apparent to those of skill in the art that certain modifications, variations, and alternative constructions would be apparent, while remaining within the spirit and scope of the invention. Although the above embodiments refer to 5G NR technology, the above embodiments may also apply to any other 3GPP technology, such as IoT technology, LTE, LTE-advanced, and/or fourth generation (4G) technology.

### Partial Glossary

3GPP 3rd generation partnership project
ACK acknowledgement
BLEP transport block error probability
BLER transport block error rate
CB code block
CRC cyclic redundancy check
DCI downlink control information
DL downlink
eMBB enhanced mobile broadband
gNB next generation NodeB
HARQ hybrid automatic repeat request
LLC low latency communication
NACK negative acknowledgement
NDI new data indicator
NR new radio
OLLA outer loop link adaptation
PHY physical layer
PRB physical resource block
SE spectral efficiency
TB transport block
TBS transport block size
UL uplink
URLLC ultra-reliable low-latency communication

1-22. (canceled)

23. An apparatus comprising:
at least one memory comprising computer program code;
at least one processor;
wherein the at least one memory and the computer program code are configured, with the at least one processor, to cause the apparatus at least to:
replace at least one code block in an enhanced mobile broadband transport block transmission with a low latency communication transmission;
transmit the enhanced mobile broadband transport block with the at least one replaced code block with the low latency communication transmission to a user equipment; and
transmit the replaced at least one code block to the user equipment using other resources.

24. The apparatus according to claim 23, wherein the at least one memory and the computer program code are configured, with the at least one processor, to cause the apparatus at least to:
generate and transmit a reservation signal to the user equipment, where the reservation signal comprises a generated transport block cyclic redundancy check for a non-punctured part of the enhanced mobile broadband transport block.

25. The apparatus according to claim 23, wherein the at least one memory and the computer program code are configured, with the at least one processor, to cause the apparatus at least to:
receive an acknowledgement or a negative acknowledgement from the user equipment relating to a non-punctured part of the enhanced mobile broadband transport block.

26. The apparatus according to claim 23, wherein the at least one memory and the computer program code are configured, with the at least one processor, to cause the apparatus at least to:
regenerate or/and reencode at least one code block in the enhanced mobile broadband transport block including a new transport block cyclic redundancy check relating to a non-punctured part of the enhanced mobile broadband transport block.

27. The apparatus according to claim 26, wherein the at least one memory and the computer program code are configured, with the at least one processor, to cause the apparatus at least to
regenerate or/and reencode the replaced at least one code block including an original transport block cyclic redundancy check.

28. The apparatus according to claim 23, wherein the transmitting of the replaced at least one code block occurs after a feedback is received from the user equipment.

29. An apparatus comprising:
at least one memory comprising computer program code;
at least one processor;
wherein the at least one memory and the computer program code are configured, with the at least one processor, to cause the apparatus at least to:
receive from a base station an enhanced mobile broadband transport block with at least one code block replaced by a low latency communication transmission; and
receive the replaced at least one code block of the enhanced mobile broadband transport block from the base station on other resources.

30. The apparatus according to claim 29, wherein the at least one memory and the computer program code are configured, with the at least one processor, to cause the apparatus at least to:
receive a reservation signal from the base station, wherein the reservation signal includes a generated transport block cyclic redundancy check for a non-punctured part of the enhanced mobile broadband transport block.

31. The apparatus according to claim 29, wherein the at least one memory and the computer program code are configured, with the at least one processor, to cause the apparatus at least to:
transmit an acknowledgement or a negative acknowledgement to the base station relating to a non-punctured part of the enhanced mobile broadband transport block.

32. The apparatus according to claim 29, wherein the at least one memory and the computer program code are configured, with the at least one processor, to cause the apparatus at least to:
receive a regenerated or reencoded at least one code block in the enhanced mobile broadband transport block including a new transport block cyclic redundancy check relating to a non-punctured part of the enhanced mobile broadband transport block.

33. The apparatus according to claim 32, wherein the received replaced at least one code block includes an original transport block cyclic redundancy check.

34. The apparatus according to claim 29, wherein the receiving of the replaced at least one code block occurs after a feedback is transmitted to the base station.

35. A method comprising:
receiving at a user equipment from a base station an enhanced mobile broadband transport block with at least one code block replaced by a low latency communication transmission; and
receiving the replaced at least one code block of the enhanced mobile broadband transport block at the user equipment from the base station on other resources.

36. The method according to claim 35, further comprising:
receiving a reservation signal from the base station, wherein the reservation signal includes a generated transport block cyclic redundancy check for a non-punctured part of the enhanced mobile broadband transport block.

37. The method according to claim 35, further comprising:
transmitting an acknowledgement or a negative acknowledgement from the user equipment to the base station relating to a non-punctured part of the enhanced mobile broadband transport block.

38. The method according to claim 35, further comprising:
receiving a regenerated or reencoded at least one code block in the enhanced mobile broadband transport block including a new transport block cyclic redundancy check relating to a non-punctured part of the enhanced mobile broadband transport block.

39. The method according to claim 38, wherein the received replaced at least one code block includes an original transport block cyclic redundancy check.

40. The method according to claim 35, wherein the receiving of the replaced at least one code block occurs after a feedback is transmitted to the base station.
